(19) United States
(12) Patent Application Publication
(10) Pub. No.: US 2002/0017682 A1
(43) Pub. Date: Feb. 14, 2002

(54) Semiconductor device

(76) Inventors: Shuming Xu, Santa Clara, CA (US); Pang Dow Foo, Singapore (SG)

Correspondence Address: Robert E. Krebs, Esq., BURNS, DOANE, SWECKER & MATHIS, L.L.P., P.O. Box 1404, Alexandria, VA, 22313-1404, US

(21) Appl. No.: 09/733,882

(22) Filed: Dec. 11, 2000

(30) Foreign Application Priority Data
Jul. 12, 2000 (SG) 200003910-7

(51) Int. Cl. H01L 21/336

(52) U.S. Cl. 257/328; 438/268; 257/263

(57) ABSTRACT

A VD (vertical diffusion) MOSFET device for use in RF power applications has a split gate structure and an additional, dummy gate is provided between the spaced apart gates and, in operation of the device, is electrically coupled to source electrodes provided outside of the gates. The split gate structure reduces gate overlap capacitance and the dummy gate induces depletion in the semiconductor body of the device and reduces the substrate capacitance. The gate overlap capacitance and the substrate capacitance both contribute to the feedback capacitance of the device which has to be as low as possible for high frequency operation. By reducing both of these components, the invention provides advantageous high frequency operation.

### FIELD OF THE INVENTION

This invention relates to a semiconductor device and more particularly, but not exclusively, concerns a VD (vertical diffusion) MOS device for use in RF (radio frequency) power applications for example.

### BACKGROUND OF THE INVENTION

A particular kind of semiconductor device, known in the art as a VDMOSFET, has been identified as being particularly useful for broadband radio frequency (RF) applications due to its high reliability and due to the existence of well tried and tested fabrication technology appropriate to its manufacture (see H. Esaki and O. Ishikawa, “A 900 MKz, VD-MOSFET with silicide gate self-aligned channel”, International Electron Devices Meeting Digest, Abstract 16.6 pp.447-449 (1984)). VD MOS devices dominate high power RF applications thanks to their high voltage capability. As compared to RF LD (lateral diffusion) MOSFETs, which are used in high frequency, narrow band applications where higher gain is needed, VDMOSFET devices are however known to exhibit a lower frequency capability due to their high parasitic feedback capacitance (Cᵣₛₛ) between gate and drain (see M. Trivedi, P. Khandelwal and K. Shenai, “Performance modeling of Power MOSFETS”, IEEE Trans. Electron Devices, Vol-46, pp.1794-1802 (1999), and M. Trivedi and K. Shenai, “Comparison of RF performance of vertical and lateral DMOSFET”, IEEE ISPSD 1999, pp.245-248). In order to reduce the parasitic feedback capacitance (Cᵣₛₛ), it has been proposed to split the unitary gate structure of the originally proposed VDMOSFET devices so that the gate comprises separate structures each of which covers just one channel region in the VDMOS structure. The resultant split gate structure, as will be explained more fully hereinafter, has the definite advantage of exhibiting a reduction in Cᵣₛₛ. because the overlap capacitance (C_{OX}) between the gate and the substrate is reduced (see the abovementioned Esaki and Ishikawa reference). However, the modified split gate structure gives rise to two drawbacks, namely: (1) the split gate structure suffers from a lower breakdown voltage due to high electric field crowding on the substrate surface under the gate ends, and (2) the substrate depletion capacitance (C_{SI}) between gate and drain is large, because there is less depletion in the substrate. Since the parasitic feedback capacitance (Cᵣₛₛ) is a function of the sum of the overlap capacitance (C_{OX}) and the substrate depletion capacitance (C_{SI}), the net result is that Cᵣₛₛ is not so much improved.

### OBJECTS AND SUMMARY OF THE INVENTION

The principal object of the present invention is to overcome or at least substantially reduce some at least of the above-mentioned drawbacks.

It is an object of the present invention also to provide a semiconductor device which is efficient and reliable for application as a radio frequency power device and which is capable of achieving one or more of a low parasitic feedback capacitance, a high breakdown voltage, a low channel resistance and a high transconductance in a controllable manner.

In broad terms, the present invention resides in the concept of taking advantage of the aforementioned split gate proposal to reduce the gate overlap capacitance C_{OX} and restoring substrate depletion to achieve a low substrate depletion capacitance C_{SI} by provision of an electrode between the spaced apart gate electrodes and appropriately biassing such electrode, for example by connecting it to the source, during operation of the device. With a low C_{OX} and a low C_{SI}, the feedback capacitance can be correspondingly low.

In accordance with an exemplary embodiment of the invention which will be described hereafter in detail, a VDMOSFET device has spaced apart sources on one face and a drain on the opposite face of a semiconductor body. Between the spaced apart sources there are provided spaced apart gate structures, and between the spaced apart gate structures there is provided an additional electrode which, in operate of the device, is connected to source. The split gate structure achieves a reduced gate overlap capacitance, just as in the prior art proposal hereinbefore described, and the additional electrode effects depletion of the underlying part of the semiconductor body and reduces the C_{SI} component of the feedback capacitance. With a reduced C_{OX} and a reduced C_{SI}, the feedback capacitance Cᵣₛₛ is much reduced and the high frequency capability of the device correspondingly enhanced.

In addition to exhibiting an enhanced high frequency capability, an additional advantageous effect is achieved by the invention in that the high electric fields caused by current crowding in the prior art split gate device are significantly reduced so that the device exhibits improved voltage breakdown levels.

The feedback capacitance Cᵣₛₛ of the hereinafter described embodiment is also relatively strongly dependent on bias conditions which is significant in regard to improving the efficiency, power gain and output power of the device.

The above and further features of the invention are set forth with particularity in the appended claims and will be described hereinafter with reference to the accompanying drawings.

### BRIEF DESCRIPTION OF THE DRAWINGS

FIG. 1 shows a prior art VDMOS device having a unitary gate structure;

FIG. 2 shows another prior art VDMOS device having a split gate structure between the spaced-apart split gates;

FIG. 3 shows an exemplary embodiment of the present invention comprising a VDMOS device as in FIG. 2 further including a dummy gate structure;

FIG. 4 shows simulated electron-hole concentration contours and current flow lines in a prior art split gate VDMOS device as shown in FIG. 2;

FIG. 5 shows simulated electron-hole concentration contours and current flow lines in a dummy gated VDMOSFET device as shown in FIG. 3 and embodying the present invention;

FIG. 6 is a graphical simulation showing how feedback capacitance (Cᵣₛₛ) varies with drain bias (V_{ds}) in the prior art devices of FIGS. 1 and 2 and in the device of FIG. 3 embodying the present invention;

FIG. 7 is a graphical showing of how measured feedback capacitance (Cᵣₛₛ) varies with drain bias (V_{ds}) in a prior art device according o FIG. 2 and in a device according to FIG. 3 embodying the present invention;

FIG. 8 is a simulated graphical showing of how feedback capacitance (Cᵣₛₛ) varies with gate bias (V_{gs}) and drain bias (V_{ds}) in the prior art device of FIG. 2 and in the device of the present invention shown in FIG. 3;

FIGS. 9A and 9B show simulated equipotential lines in, respectively the prior art device of FIG. 2 and the device of the present invention shown in FIG. 3, strong electric field crowding at the gate ends being shown in FIG. 9A and much reduced field strength at the gate ends being shown in FIG. 9B;

FIG. 10 shows measured breakdown voltage-drain current characteristics in respect of a prior art device according to FIG. 2 and a device according to the present invention as shown in FIG. 3;

FIG. 11 shows measured transfer current-voltage characteristics in respect of a prior art device according to FIG. 2 and a device according to the present invention as shown in FIG. 3; and

FIG. 12 shows measured on-state current-voltage characteristics in respect of a prior art device according to FIG. 2 and a device according to the present invention as shown in FIG. 3.

### DETAILED DESCRIPTION OF THE EMBODIMENTS

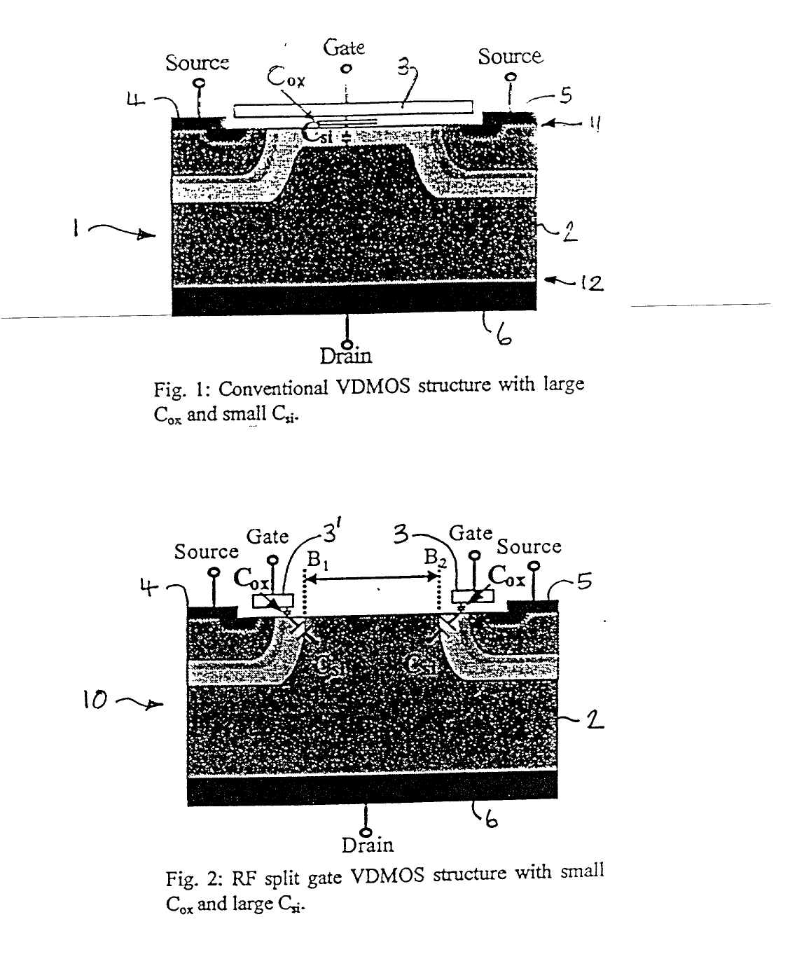

A conventional VDMOS structure, as originally proposed and as well known, is schematically illustrated in FIG. 1. As shown, the device generally indicated by 1, comprises an N− silicon semiconductor body 2, having a unitary gate 3 and two spaced-apart sources 4, 5 at its upper surface 11 and a drain 6 at its lower surface 12. The sources 4, 5 couple to respective N+ regions 7 located within P− type bodies 8 formed in the N− silicon body which is an epitaxial layer formed on an N+ substrate. As is also well known in the art, the amount of capacitive coupling between the gate and the drain limits the high frequency capability of the device such that that the device of FIG. 1 operates at a lower frequency capability than conventional RF LDMOSFET devices. The high frequency capability of a VDMOS device is a function of its feedback capacitance (Cᵣₛₛ) which, in turn, depends upon two factors, namely the gate-substrate overlap capacitance (C_{OX}) and the silicon substrate depletion capacitance (C_{SI}). The feedback capacitance Cᵣₛₛ. can be described as:

$${C}_{rss} = \frac{{C}_{ox} * {C}_{S1}}{{C}_{ox} + {C}_{S1}}$$

The overlap capacitance C_{OX} is determined by the gate/substrate overlap area and the thickness of the gate oxide insulation, while the substrate depletion capacitance C_{SI} is related to the doping concentration of the silicon body. C_{OX} is substantially constant but C_{SI} changes with drain bias. To get a low Cᵣₛₛ, both C_{OX} and C_{SI} must be minimised. With increasing drain bias, C_{SI} decreases due to the substrate depletion caused by reverse biasing of its p-body junction and the influence of the gate. This makes Cᵣₛₛ decrease very quickly with increased drain bias. Due to the high gate/substrate overlap area, however, C_{OX} in the conventional low frequency VDMOS of FIG. 1 is very large.

FIG. 2 uses the same reference numerals as were used to designate same/like parts in the description of FIG. 1 and shows another VDMOS structure 10 which is similar to the structure of FIG. 1, the difference being that the gate region is split to form two separate gate portions 3 and 3′ at the upper surface 11 which just cover the channel, that is to say the gate is truncated beyond the p-body diffusion edges to minimise gate-drain overlap capacitance for improved RF performance. The split gate structure of FIG. 2 exhibits a definite advantage over the FIG. 1 structure in that its associated gate overlap capacitance C_{OX} is reduced. However, since the substrate 2 depletes only around the p-body junctions and there is no depletion between the points B₁ and B₂ shown in the Figure, the substrate depletion capacitance C_{SI} associated with the split gate structure is disadvantageously large in comparison to that of the FIG. 1 structure. The result of this is that the feedback capacitance Cᵣₛₛ is not reduced correspondingly with the reduction of C_{OX}. Another, serious drawback of the FIG. 2 structure is that the interrupted gate structure unavoidably leads to electric field crowding at the gate ends which causes the breakdown voltage of the device 10 to be reduced.

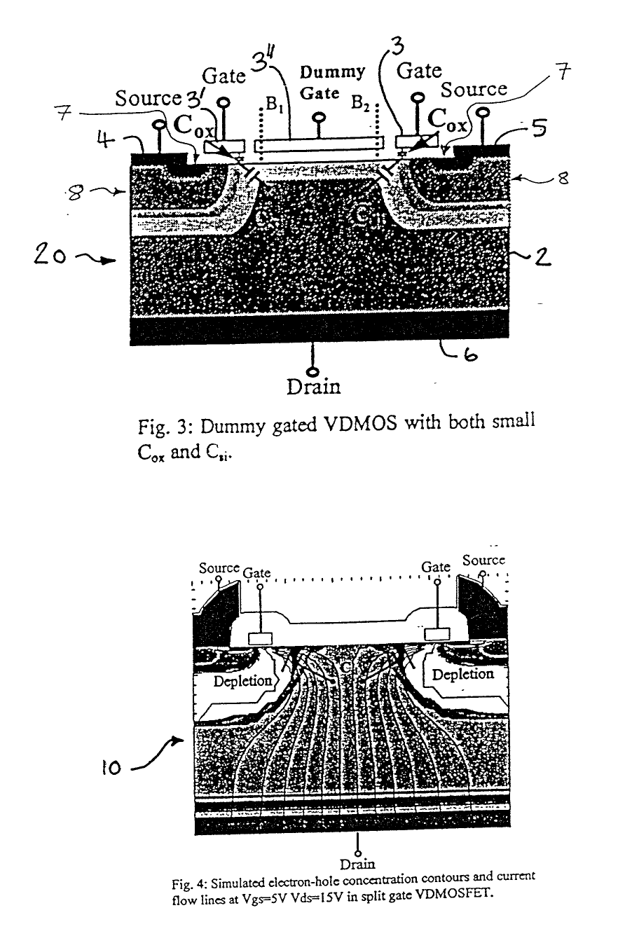

FIG. 3 illustrates an improved VDMOS device structure according to the present invention. FIG. 3 uses the same reference numerals as were used to designate same/like parts in the description of FIGS. 1 and 2. The arrangement, generally indicated by 20, is the same as that of FIG. 2 except that there is an additional electrode 3″, hereinafter referred to as a dummy gate, between the split gate electrodes 3 and 3′, the dummy gate 3″ extending just beyond the points B₁ and B₂ shown in the Figure and having its ends spaced apart from the adjoining ends of respective ones of the gates 3,3′ by a distance of the order of 1 μm.

The device 20 shown in FIG. 3 advantageously provides both a reduced gate-drain overlap capacitance C_{OX} and a reduced substrate capacitance C_{SI}. In operation, the centrally-positioned dummy gate region 3″ may be shorted to source so that, when a positive drain bias is applied to the device, charge carriers are caused to be depleted in the substrate body 2, not only around the p-bodies but also in the centre of the substrate. This reduces the substrate capacitance C_{SI} leading to a fast decrease of the feedback capacitance Cᵣₛₛ with drain bias. Because the two gate portions 3 and 3′ function in the same way as those of the split gate structure of FIG. 2, the overlap capacitance C_{OX} characteristic of the device 20 is as low as that in the split gate structure. Further, because both C_{OX} and C_{SI} are effectively reduced, the feedback capacitance characteristic Cᵣₛₛ of the device 20 is reduced to a much lower level than in the FIG. 2 device. Moreover, when the device 20 is in its off-state with Vgs zero and the drain having to support a high voltage, the dummy gate protects the active gate ends from electric field crowding, as will be more fully described hereinafter, leading to a lower electric field at the gate ends and to a correspondingly high breakdown voltage in the device 20.

The device of FIG. 3 may be fabricated employing conventional and well known semiconductor device fabrication techniques. For example, an N+ silicon substrate formed with an N− epitaxial layer has a MOSFET fabrication region defined on the surface of its N− layer by formation of spaced apart silicon oxide layers. Within this region a gate oxide layer is formed and spaced-apart gate electrodes and an intermediate dummy gate electrode are formed on the gate oxide layer. By ion implantation of suitable dopants followed by thermal diffusion, P− type bodies are then formed under the two spaced-apart gate electrodes and extending to the edges of the MOSFET fabrication region. N+ source regions are then formed in the P− type bodies, and the gate oxide layer is selectively removed to permit the formation of source electrodes on the N+ regions. The drain electrode may then be provided on the opposite side of the device.

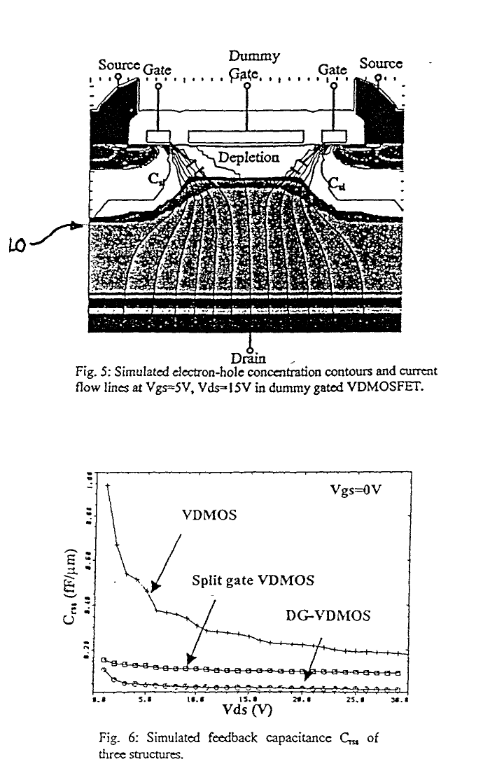

FIG. 4 shows simulated electron hole concentration contours and current flow lines under 5V-gate bias and 28V-drain bias in the FIG. 2 VDMOSFET with a split gate structure. It can be seen that only the area around the p-bodies are depleted of carriers. There is no depletion in the centre of the substrate. FIG. 5 shows simulated depletion contours and current flow lines in the dummy gated VDMOS of FIG. 3 under the same bias conditions. In contrast to the split gate VDMOSFET structure of FIG. 2, in the dummy gated VDMOSFET structure of FIG. 3, the substrate depletes not only around the p-bodies, but also around the whole centre of the substrate, leading to a low C_{SI}. Thus, both C_{OX} and C_{SI} are minimised in the dummy gate structure, as previously discussed hereinabove.

FIG. 6 shows simulated Cᵣₛₛ vs. Vds characteristics for the three structures of FIGS. 1, 2 and 3. For the conventional structure of FIG. 1, Cᵣₛₛ at zero bias is relatively large. This is attributed to a large C_{OX}. With increasing drain bias, Cᵣₛₛ decreases very quickly in the FIG. 1 structure due to strong depletion in the substrate. Compared to the conventional VDMOS of FIG. 1, the split gate VDMOS of FIG. 2 exhibits a much lower C_{OX}, but Cᵣₛₛ decreases in the FIG. 2 structure at a much slower rate with increasing drain bias than in the FIG. 1 structure due to the silicon substrate undergoing less depletion so that C_{SI} is greater. For the dummy gated VDMOS of FIG. 3, Cᵣₛₛ at zero bias is comparatively low, as in the FIG. 2 device, since the active gate area is reduced so as to result a small C_{OX} and moreover, in contrast to the split gate VDMOS of FIG. 2, Cᵣₛₛ of the dummy gated structure decreases very quickly with increasing drain bias, thereby achieving the smallest Cᵣₛₛ of the three structures, since C_{SI} is reduced as a result of the increased substrate depletion caused by provision of dummy gate 3″.

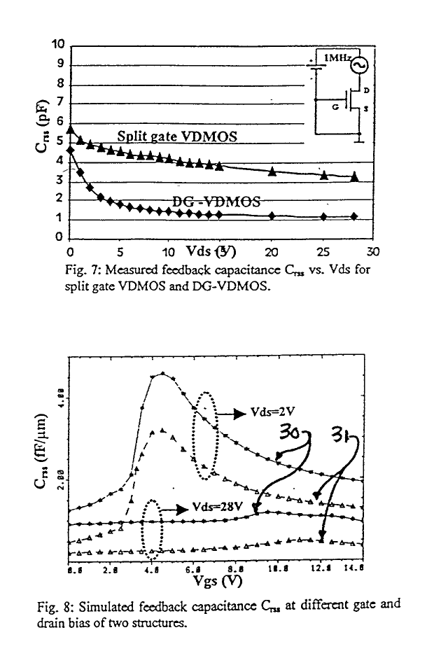

Measured Cᵣₛₛ curves at Vgs=OV are shown in FIG. 7. 500 MHz-30 W devices were fabricated according to the split gate and dummy gate structures of FIGS. 2 and 3 respectively using standard RF VDMOS process technology which is well known and need not be described here. The spacing between the active gates and dummy gate was 1 μm. Both devices exhibited almost the same Cᵣₛₛ at zero drain bias, because C_{OX} is the same and C_{SI} at zero bias is almost the same for both devices. However, with increasing drain bias (V_{ds}), the two devices behaved very differently. For the split gate structure, Cᵣₛₛ decreased very gently. At 5V-drain bias, Cᵣₛₛ was 4.5 pF. Even with 28V drain bias, Cᵣₛₛ was still as high as 3.2 pF. In contrast to this, Cᵣₛₛ in the dummy gated VDMOS device decreased much more quickly. At 5V-drain bias, it reduced to only 1.8 pF. It further dropped to as low as 1.1 pF at 28V-drain bias, thereby achieving a three fold improvement as compared to the FIG. 2 split gate structure. This benefits the RF performance of the device very significantly.

The Cᵣₛₛ characteristic in the on-state for the conventional split gate VDMOS and the dummy gated VDMOS devices of FIGS. 2 and 3 respectively were also investigated using simulation. FIG. 8 shows the simulated Cᵣₛₛ vs. Vgs characteristics for split gate 30 and dummy gate 31 structures at Vds=2V and Vds=28V, respectively. It can be seen that for any given bias point, the dummy gated VDMOSFET showed a significantly lower Cᵣₛₛ than the conventional split gate VDMOSFET.

It can also be seen from FIG. 8 that Cᵣₛₛ changes dramatically with different Vds˜Vgs bias conditions. With Vds=2V, the substrate depletes lightly, C_{SI} is large and Cᵣₛₛ is strongly influenced by C_{OX} which changes significantly with different gate bias conditions according to whether the device is operating in a sub-threshold region, a linear region or a saturated region. At 28V drain bias, the substrate depletes deeply, C_{SI} becomes very small and variation of gate bias has little influence on Cᵣₛₛ. It is clear from FIG. 8 that, because the dummy gate structure induces full depletion of the substrate, Cᵣₛₛ in the dummy gated VDMOS is much lower than that in the split gate VDMOS and not only is this the case at low drain bias but also it is the case at high drain bias. At the Vgs=10V and Vds=28V operation point for example, Cᵣₛₛ is 1.2 fF/ μm in the split gate structure and is only 0.4 fF/μm in the dummy gate structure. A low feedback capacitance Cᵣₛₛ is very important for RF circuit design.

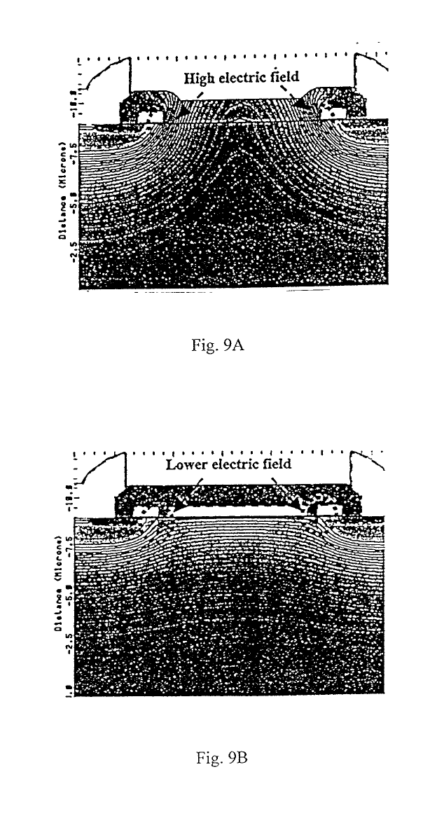

In addition to low feedback capacitance, the dummy gated VDMOS of the invention also achieves a higher breakdown voltage and higher reliability. In this connection, FIG. 9a shows simulated equipotential lines for the split gate VDMOS structure of FIG. 2 and it can be seen that the potential lines are unevenly vertically distributed around the gates. There is sharp electric field crowding at the gate edges, causing a low breakdown voltage. In contrast to this, as can be seen from FIG. 9b, equipotential lines for the dummy gated VDMOS structure of FIG. 3 are parallel and uniformly distributed under the gates. Thus, the electric field crowding effect is significantly diminished in the dummy gated VDMOS device of the invention, ensuring a higher breakdown voltage.

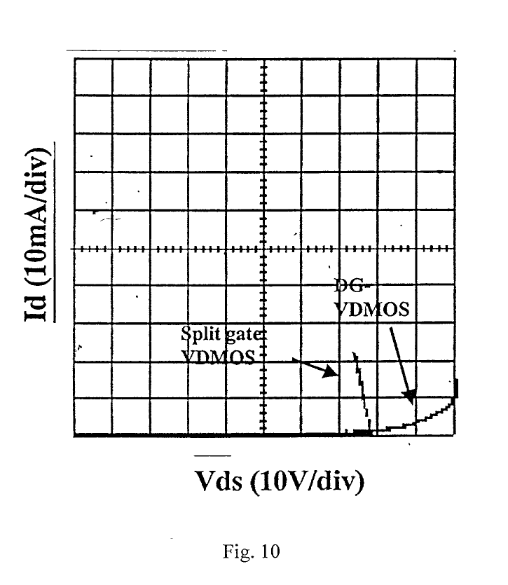

Measurement results in respect of the breakdown voltage characteristics for the split gate and dummy gated structures of FIGS. 2 and 3 respectively are shown in FIG. 10. The breakdown voltage was only 78V for the split gate VDMOS device, and was improved to more than 100V for the dummy gated VDMOS.

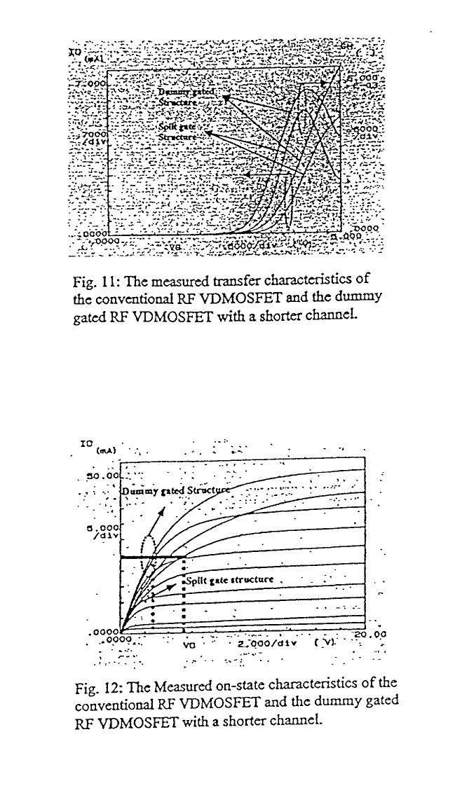

The dummy gate structure proposed by the present invention thus reduces the electric field in the channel regions as can be seen in FIG. 9b. It improves the channel length modulation. This allows the channel length to be reduced without suffering significant short channel degradation, thus achieving a higher transconductance Gm. This is shown in FIG. 11 which shows measured transfer characteristics for the split gate and dummy gated structures. Owing to the abovementioned beneficial short channel capability, the on-state resistance of the dummy gate structure can also be significantly reduced. In this connection, FIG. 12 shows measured on-state characteristics of the conventional split gate structure of FIG. 2 and of the short channel dummy gated structure of FIG. 3. As shown in FIG. 12, for the same current level the on-state voltage drop was 5.5V for the split gate device and reduced to only 2.3V for the dummy gated device of the invention. This improves the efficiency, power gain and output power of the device. Not only does the dummy gated device of the invention have an improved high frequency capability, therefore, it also has these significant additional attributes.

Having described the invention by reference to a specific embodiment, it is to be well understood that the embodiment is exemplary only and that modifications and variations thereto will occur to those possessed of appropriate skills without departure from the spirit and scope of the present invention as set forth in the appended claims. For example, whereas the described embodiment of the invention has three gates, namely two spaced apart active gates and a central dummy gate, and two spaced apart sources arranged outside of the gates, the same or a similar technical effect could be obtained in alternative VDMOS structures. For example, where a central source is provided between two spaced apart active gates, the advantages of the invention could be obtained by provision of dummy gates outside of the active gates but still overlying the drain region. The invention can be applied to any VDMOS structure so long as the dummy gate is designed to overly the drain region.

1. A VDMOS device having source, gate and drain electrodes and wherein a further electrode is provided which, in operation of the device, has the effect of enhancing the high frequency capability of the device.

2. A VDMOS device as claimed in claim 1 having spaced apart gate electrodes for reduced gate overlap capacitance.

3. A VDMOS device as claimed in claim 2 wherein said further electrode is located between and spaced apart from both of said gate electrodes.

4. A VDMOS device as claimed in claim 2 or 3 having spaced apart source electrodes.

5. A VDMOS device as claimed in claim 4 wherein said spaced apart source electrodes are located outside of said spaced apart gate electrodes.

6. A VDMOS device as claimed in any preceding claim wherein said further electrode is connected to said source electrode(s).

7. A VDMOS device as claimed in any preceding claim wherein said further electrode is arranged to reduce current crowding in operation of the device.

8. A method of manufacturing a VDMOS device, wherein an electrode is provided in the device in addition to the source, gate and drain electrodes, said additional electrode being arranged in the device to enhance its high frequency operating capability.

9. A method as claimed in claim 8 wherein said additional electrode is produced with said gate electrode.

10. A semiconductor device comprising a semiconductor body having electrodes spaced on opposite sides thereof for current flow therebetween in dependence upon a control signal from a control electrode, and wherein means are additionally provided for inducing carrier depletion in the semiconductor body so as to reduce the capacitance of the device and enhance its high frequency capability.

11. A semiconductor device as claimed in claim 10 configured as a field effect transistor.

12. A semiconductor device as claimed in claim 11 wherein source and gate electrodes are provided on one side of said semiconductor body and a drain electrode is provided on the opposite side of said semiconductor body.

13. A semiconductor device as claimed in claim 12 wherein there are spaced apart gate electrodes and said means for inducing carrier depletion comprises a further electrode between said gate electrodes.

14. A semiconductor device as claimed in claim 13 wherein spaced apart source electrodes are provided on opposite sides of said spaced apart gate electrodes.

15. A VDMOSFET split gate device having a further electrode between the gate electrodes.

16. A method of enhancing the high frequency response of a VDMOS device comprising providing an additional electrode in the device for causing depletion in the semiconductor body of the device.
